(19) United States
(12) Patent Application Publication
(10) Pub. No.: US 2015/0179444 A1
(43) Pub. Date: Jun. 25, 2015

(54) Methods for Forming Crystalline IGZO Through Power Supply Mode Optimization

(71) Applicants: LG Display Co., Ltd., Seoul (KR); Intermolecular, Inc., San Jose, CA (US)

(72) Inventors: Sang Lee, San Jose, CA (US); Yoon-Kyung Chang, Gyeonggi-do (KR); Seon-Mee Cho, Santa Clara, CA (US); Min-Cheol Kim, Gyeonggi-do (KR); Kwon-Sik Park, Gangnam-gu (KR); Woosup Shin, Gyeonggi-do (KR)

(73) Assignees: LG Display Co., Ltd., Seoul (KR); Intermolecular, Inc., San Jose, CA (US)

(21) Appl. No.: 14/139,195

(22) Filed: Dec. 23, 2013

(51) Int. Cl. H01L 21/02; H01L 29/786; H01L 29/66

(52) U.S. Cl. CPC H01L 21/02554; H01L 21/02631; H01L 21/0262; H01L 29/66969; H01L 29/7869

(57) ABSTRACT

Embodiments described herein provide method for forming crystalline indium-gallium-zinc oxide (IGZO). A substrate is positioned relative to at least one target. The at least one target includes indium, gallium, zinc, or a combination thereof. A substantially constant voltage is provided across the substrate and the at least one target to cause a plasma species to impact the at least one target. The impacting of the plasma species on the at least one target causes material to be ejected from the at least one target to form an IGZO layer above the substrate.

### TECHNICAL FIELD

The present invention relates to indium-gallium-zinc oxide (IGZO). More particularly, this invention relates to methods for forming crystalline IGZO, as well as methods for forming IGZO devices, such as IGZO thin film transistors (TFTs), incorporating crystalline IGZO.

### BACKGROUND OF THE INVENTION

Indium-gallium-zinc oxide (IGZO) devices, such as IGZO thin-film transistors (TFTs) have attracted a considerable amount of attention due to the associated low cost, room temperature manufacturing processes with good uniformity control, high mobility for high speed operation, and the compatibility with transparent, flexible, and light display applications. Due to these attributes, IGZO TFTs may even be favored over low cost amorphous silicon TFTs and relatively high mobility polycrystalline silicon TFT for display device applications. IGZO devices typically utilize amorphous IGZO (a-IGZO).

Recent developments in the field suggest that the use of crystalline IGZO may provide improved electrical and chemical stability. However, little work has been done to determine how to form crystalline IGZO, or convert a-IGZO to crystalline IGZO, using already-existing manufacturing and processing equipment.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a cross-sectional view of a substrate with gate electrode formed above.

FIG. 2 is a cross-sectional view of the substrate of FIG. 1 with a gate dielectric layer formed above the gate electrode and the substrate.

FIG. 3 is a cross-sectional view of the substrate of FIG. 2 with an indium-gallium-zinc oxide (IGZO) channel layer formed above the gate dielectric layer.

FIG. 4 is a cross-sectional view of the substrate of FIG. 4 with an etch-stop layer formed above the IGZO layer.

FIG. 5 is a cross-sectional view of the substrate of FIG. 4 with source and drain regions formed above the etch-stop layer.

FIG. 6 is a cross-sectional view of the substrate of FIG. 5 with a passivation layer formed above the source and drain regions.

FIG. 7 is a graph depicting X-ray diffraction (XRD) crystalline peak heights of IGZO formed using a physical vapor deposition (PVD) process using various plasma voltages.

FIG. 8 is a graph depicting the kinetic energy for indium, gallium, zinc, and oxygen ejected from targets during a PVD process from various plasma voltages, as obtained using simulation software.

FIG. 9 is a simplified cross-sectional diagram illustrating a PVD tool according to some embodiments.

FIG. 10 is a flow chart illustrating a method for forming crystalline IGZO according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Some embodiments described herein provide methods for improving the electrical and chemical stability of indium-gallium-zinc oxide (IGZO). In particular, embodiments described herein methods for enhancing the crystalline structure of the IGZO along the c-axis (i.e., along the (009) plane, which is in the direction perpendicular to the substrate), which improves the electrical and chemical stability of the IGZO.

In some embodiments, this is accomplished by depositing the IGZO using a physical vapor deposition (PVD) process, such as sputtering, in which the voltage across the target(s) and the substrate (i.e., the plasma voltage) is held constant, or substantially constant. That is, the PVD is operated in the constant-voltage mode, as opposed to the constant-power mode (which is typically used) or the constant-current mode. In some embodiments, the plasma voltage is held constant, or substantially constant, above 200 volts (V), such as between about 300 V and about 600 V, by, for example, setting the current limit properly so that power supply may sustain constant voltage mode operation.

Operating the PVD tool at a constant (e.g., and relatively high) plasma voltage causes the charged plasma species to impact the target(s) with higher kinetic energy, which in turns causes the material sputtered from the target(s) to be ejected with higher kinetic energy. As a result, the sputtered particles impact the substrate with greater mobility, increasing the probability that they find a relatively stable energy site within the sputtered material (i.e., with a more crystalline structure). The IGZO may be formed as a channel (or channel layer) in an IGZO thin-film transistor (TFT).

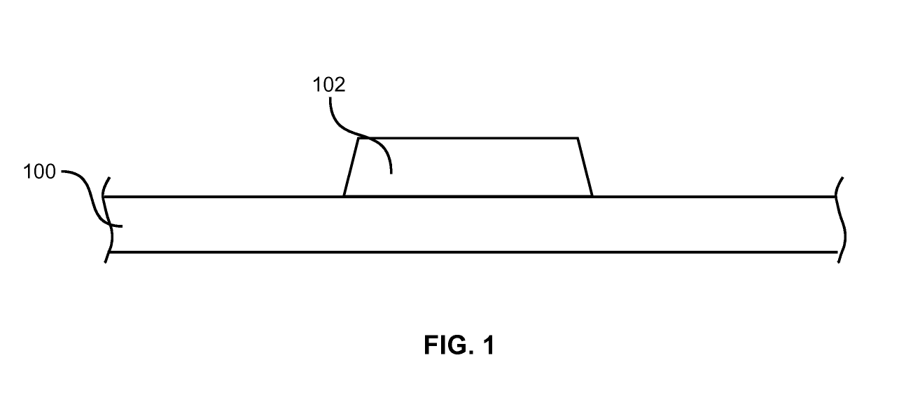

FIGS. 1-6 illustrate a method for forming an IGZO thin film transistor (or more generically, an IGZO device), according to some embodiments. Referring now to FIG. 1, a substrate 100 is shown. In some embodiments, the substrate 100 is transparent and is made of, for example, glass. The substrate 100 may have a thickness of, for example, between 0.01 and 2.0 centimeters (cm). Although only a portion of the substrate 100 is shown, it should be understood that the substrate 100 may have a width of, for example, between 5.0 cm and 4.0 meters (m). Although not shown, in some embodiments, the substrate 102 may have a dielectric layer (e.g., silicon oxide) formed above an upper surface thereof. In such embodiments, the components described below are formed above the dielectric layer.

Still referring to FIG. 1, a gate electrode 102 is formed above the transparent substrate 100. In some embodiments, the gate electrode 102 is made of a conductive material, such as copper, silver, aluminum, manganese, molybdenum, or a combination thereof. The gate electrode may have a thickness of, for example, between about 20 nanometers (nm) and about 500 nm. Although not shown, it should be understood that in some embodiments, a seed layer is formed between the substrate 100 and the gate electrode 102. In some embodiments, the seed layer includes copper and has a thickness of, for example, between about 1 nm and about 5 nm. The seed layer may be made of, for example, copper-manganese alloy (e.g., 96-99% copper and 1-4% manganese) or else.

It should be understood that the various components on the substrate, such as the gate electrode 102 and those described below, are formed using processing techniques suitable for the particular materials being deposited, such as PVD (e.g., co-sputtering in some embodiments), chemical vapor deposition (CVD), electroplating, etc. Furthermore, although not specifically shown in the figures, it should be understood that the various components on the substrate 100, such as the gate electrode 102, may be sized and shaped using a photolithography process and an etching process, as is commonly understood, such that the components are formed above selected regions of the substrate 100.

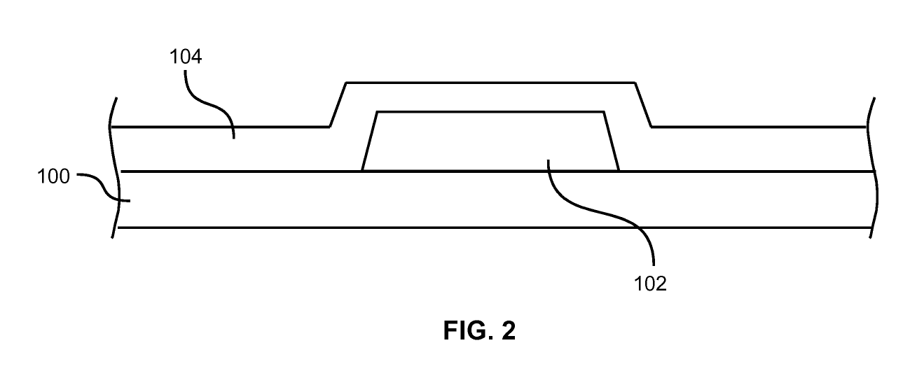

Referring to FIG. 2, a gate dielectric layer 104 is then formed above the gate electrode 102 and the exposed portions of the substrate 100. The gate dielectric layer 104 may be made of, for example, a high-k dielectric (e.g., having a dielectric constant greater than 3.9), such as zirconium oxide, hafnium oxide, or aluminum oxide. In some embodiments, the gate dielectric layer 104 has a thickness of, for example, between about 10 nm and about 500 nm.

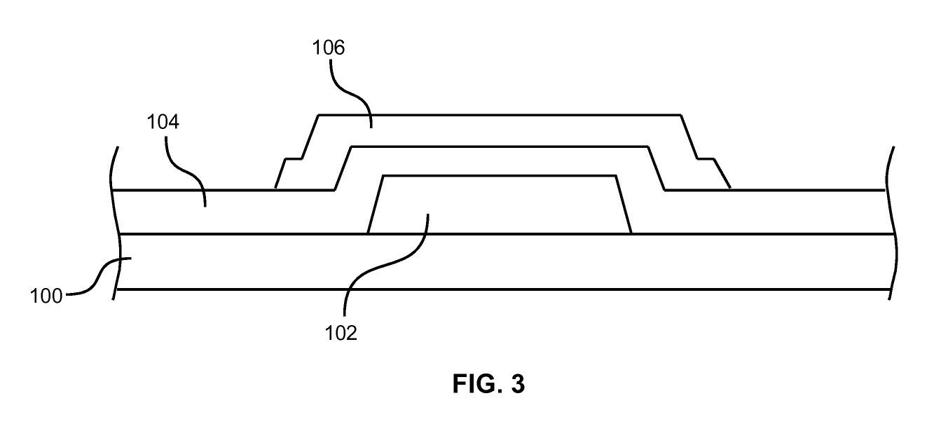

As shown in FIG. 3, an IGZO channel layer (or active layer) 106 is then formed above the gate dielectric layer 104, over the gate electrode 102. The IGZO channel layer 106 may be made of IGZO in which a ratio of the respective elements is 1:1:1:1-3. The IGZO channel layer 106 may have a thickness of, for example, between about 10 nm and about 100 nm.

The IGZO channel layer 106 (or at least the IGZO layer from which the IGZO channel layer 106 is formed), perhaps along with some of the other components described, may be formed using a PVD tool which may be operable in a constant-power mode, a constant-current mode, and a constant-voltage mode, as is commonly understood in the art. In some embodiments, the IGZO used in the IGZO channel layer 106 is deposited using a PVD tool operating in the constant-voltage mode (i.e., while maintaining a substantially constant voltage across the substrate and the target(s) from which the IGZO is ejected). During the deposition process, the voltage may be maintained above 200 V, such as between about 200 V and about 600 V, preferably between about 300 V and about 600 V. As described in more detail below, operating the PVD tool in such a way enhances the crystalline structure of the IGZO. In some embodiments, the IGZO is deposited from a single target that includes indium, gallium, and zinc (e.g., an indium-gallium-zinc alloy target or an IGZO target), while in some embodiments, two or more targets are used (e.g., co-sputtering with an indium-zinc target and a gallium target).

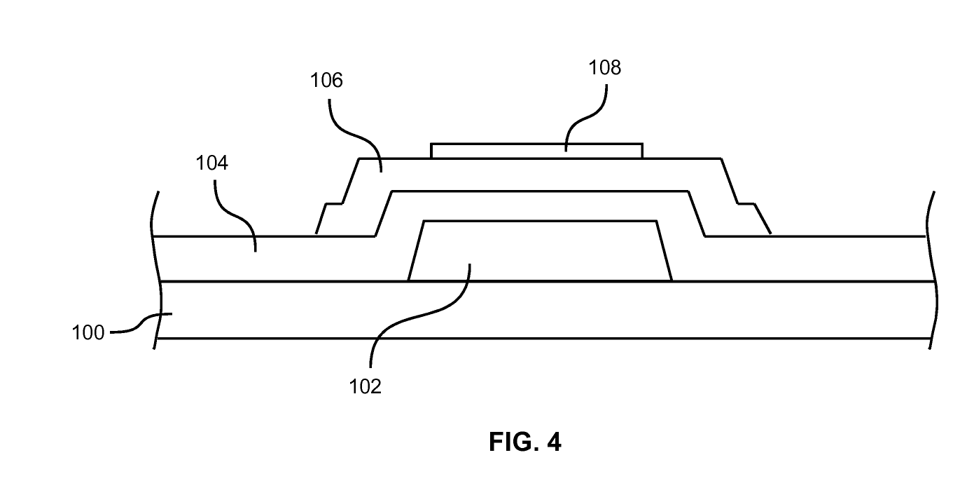

Although not specifically shown, in some embodiments, the IGZO channel layer 106 (and the other components shown in FIG. 4) may then undergo an annealing process. In some embodiments, the annealing process includes a relatively low temperature (e.g., less than about 500° C., preferably less than 450° C.) heating process in, for example, an ambient gaseous environment (e.g., nitrogen ambient or air) to further enhance the crystalline structure of the IGZO. The heating process may occur for between about 1 minutes and about 200 minutes.

Referring now to FIG. 4, an etch-stop layer 108 is then formed above the IGZO channel layer 106. In some embodiments, the etch-stop layer 108 is made of a high-k dielectric, such as aluminum oxide and/or hafnium oxide. The etch-stop layer 108 may have a thickness of, for example, between about 10 nm and about 500 nm. It should be understood that in some embodiments, a conventional etch-stop layer is not formed above the IGZO channel layer 106, but rather the source and drain regions (described below) are selectively etched using a “back-channel etch” (BCE) process, as is commonly understood.

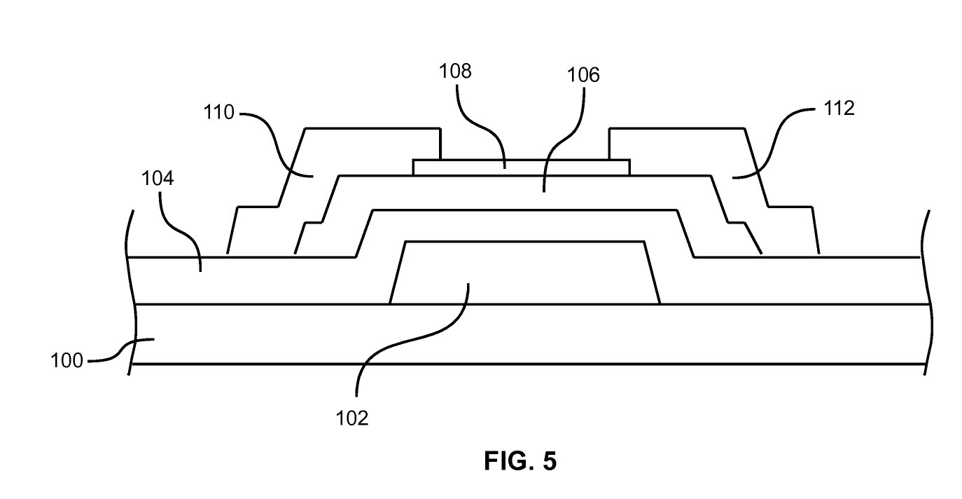

Next, as shown in FIG. 5, a source region (or electrode) 110 and a drain region (or electrode) 112 are formed above the IGZO channel layer 106. As shown, the source region 110 and the drain region 112 lie on opposing sides of, and partially overlap the ends of, the etch-stop layer 108 (which may be used to protect the IGZO channel layer 106 during an etch process used to define the source region 110 and the drain region 112). In some embodiments, the source region 110 and the drain region 112 are made of titanium, molybdenum, copper, copper-manganese alloy, or a combination thereof. The source region 110 and the drain regions 112 may have a thickness of, for example, between about 20 nm and 500 nm.

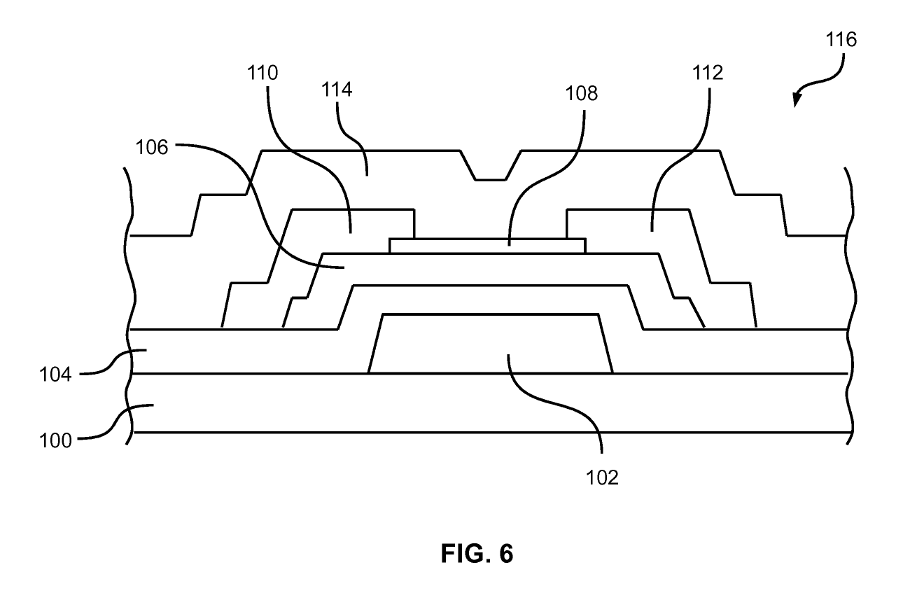

Referring to FIG. 6, a passivation layer 114 is then formed above the source region 110, the drain region 112, the etch-stop layer 108, and the gate dielectric layer 104. In some embodiments, the passivation layer 114 is made of silicon oxide, silicon nitride, aluminum oxide, aluminum nitride, or a combination thereof and has a thickness of, for example, between about 0.1 μm and about 1.5 μm.

The deposition of the passivation layer 114 may substantially complete the formation of an IGZO device 116, such as an inverted, staggered bottom-gate IGZO TFT. It should be understood that although only a single device 116 is shown as being formed on a particular portion of the substrate 100 in FIGS. 1-6, the manufacturing processes described above may be simultaneously performed on multiple portions of the substrate 100 such that multiple devices 116 are simultaneously formed, as is commonly understood.

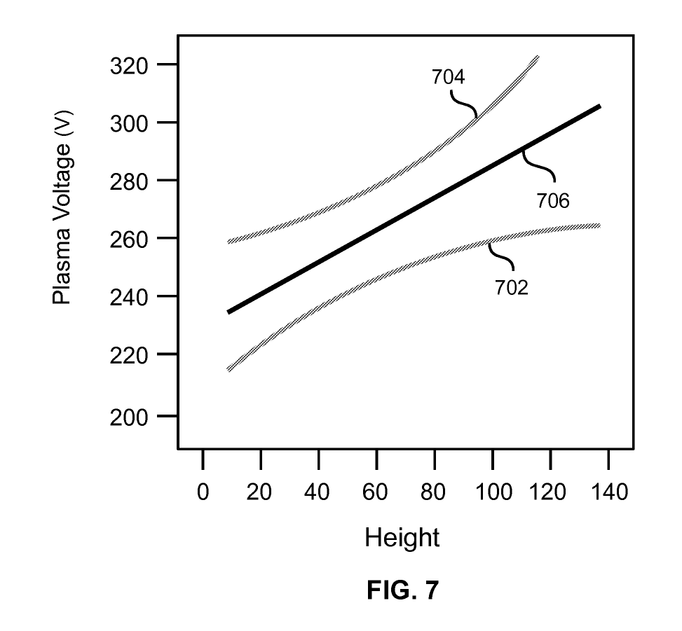

FIG. 7 graphically illustrates PVD plasma voltages (or voltage ranges) which may be used to form various scattering intensities of the (009) crystalline peak in deposited IGZO, as determined using X-ray diffraction (XRD). At each height, line 702 depicts a lower bound of the voltage range, line 704 depicts an upper bound for the voltage range, and line 706 depicts the mean (or average) voltage range. As shown, as the plasma voltage is increased, the scattering intensity of the (009) crystalline peak also increases. Thus, in general, increasing the plasma voltages enhances the crystalline structure along the (009) plane.

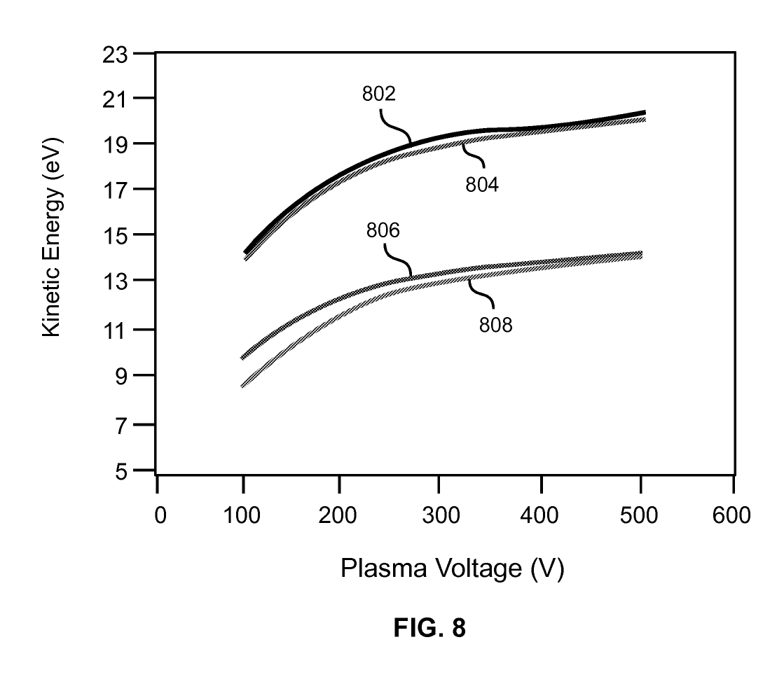

FIG. 8 graphically illustrates the kinetic energy (eV) of indium, gallium, zinc, and oxygen ejected from PVD targets at various plasma voltages, as obtained using simulation software. Line 802 depicts the kinetic energy for sputtered indium, line 804 depicts the kinetic energy for sputtered gallium, line 806 depicts the kinetic energy for sputtered zinc, and line 808 depicts the kinetic energy for oxygen. As shown, the kinetic energy for indium, gallium, zinc, and oxygen increases as the plasma voltage is increased. Thus, in general, increasing the plasma voltage causes the material ejected from the PVD targets to have higher kinetic energy.

The enhancement of the crystalline structure of the IGZO which occurs from operating the PVD tool at higher plasma voltages may be the result of the increased kinetic energy of the particles ejected from the targets. In particular, the increased kinetic energy may provide additional mobility to the particles as they impact the substrate (and/or the previously deposited IGZO) such that the probability that they find a relatively stable energy site within the sputtered material (i.e., with a more crystalline structure) is increased.

The enhanced crystalline structure of the IGZO may improve both the electrical and chemical stability of the IGZO. When utilized in an IGZO device, such as the IGZO TFT described above, the crystalline IGZO may improve device performance, especially with respect to reliability and longevity. Additionally, it should be noted that the methods described herein may be easily incorporated into already-existing IGZO device manufacturing processes and equipment.

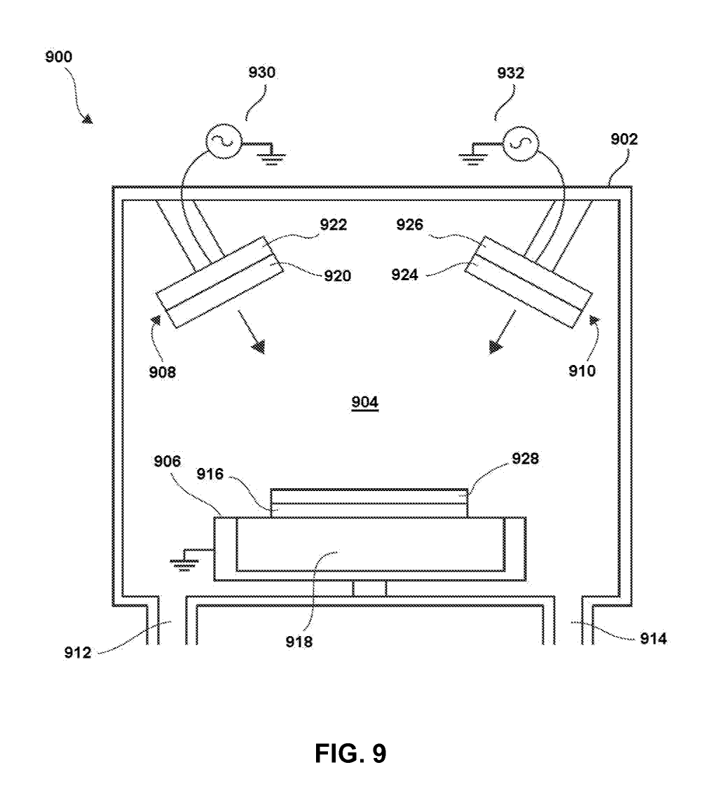

FIG. 9 provides a simplified illustration of a physical vapor deposition (PVD) tool (and/or system) 900 which may be used, in some embodiments, to form an IGZO layer (and/or other components of the IGZO device) described above. The PVD tool 900 shown in FIG. 9 includes a housing 902 that defines, or encloses, a processing chamber 904, a substrate support 906, a first target assembly 908, and a second target assembly 910.

The housing 902 includes a gas inlet 912 and a gas outlet 914 near a lower region thereof on opposing sides of the substrate support 906. The substrate support 906 is positioned near the lower region of the housing 902 and in configured to support a substrate 916. The substrate 916 may be a round substrate having a diameter of, for example, about 200 mm or about 300 mm. In other embodiments (such as in a manufacturing environment), the substrate 916 may have other shapes, such as square or rectangular, and may be significantly larger (e.g., about 0.5-about 6 m across). The substrate support 906 includes a support electrode 918 and is held at ground potential during processing, as indicated.

The first and second target assemblies (or process heads) 908 and 910 are suspended from an upper region of the housing 902 within the processing chamber 904. The first target assembly 908 includes a first target 920 and a first target electrode 922, and the second target assembly 910 includes a second target 924 and a second target electrode 926. As shown, the first target 920 and the second target 924 are oriented or directed towards the substrate 916. As is commonly understood, the first target 920 and the second target 924 include one or more materials that are to be used to deposit a layer of material 928 on the upper surface of the substrate 916.

The materials used in the targets 920 and 924 may, for example, include indium, gallium, tin, zinc, tin, silicon, silver, aluminum, manganese, molybdenum, zirconium, hathium, titanium, molybdenum, copper, or any combination thereof (i.e., a single target may be made of an alloy of several metals). Additionally, the materials used in the targets may include oxygen, nitrogen, or a combination of oxygen and nitrogen in order to form oxides, nitrides, and oxynitrides. Additionally, although only two targets 920 and 924 are shown, additional targets may be used.

The PVD tool 900 also includes a first power supply 930 coupled to the first target electrode 922 and a second power supply 932 coupled to the second target electrode 924. As is commonly understood, in some embodiments, the power supplies 930 and 932 pulse direct current (DC) power to the respective electrodes, causing material to be, at least in some embodiments, simultaneously sputtered (i.e., co-sputtered) from the first and second targets 920 and 924. In some embodiments, the power is alternating current (AC) to assist in directing the ejected material towards the substrate 916.

During sputtering, inert gases (or a plasma species), such as argon or krypton, may be introduced into the processing chamber 904 through the gas inlet 912, while a vacuum is applied to the gas outlet 914. The inert gas(es) may be used to impact the targets 920 and 924 and eject material therefrom, as is commonly understood. In embodiments in which reactive sputtering is used, reactive gases, such as oxygen and/or nitrogen, may also be introduced, which interact with particles ejected from the targets (i.e., to form oxides, nitrides, and/or oxynitrides).

Although not shown in FIG. 9, the PVD tool 900 may also include a control system having, for example, a processor and a memory, which is in operable communication with the other components shown in FIG. 9 and configured to control the operation thereof in order to perform the methods described herein. In some embodiments, the PVD tool 900 (and/or the control system) is operable in a constant-power mode, a constant-current mode, and a constant-voltage mode, as is commonly understood in the art.

As described above, in some embodiments, the PVD tool is operated in the constant-voltage mode during the deposition of the IGZO used to form, for example, the IGZO channel layer 106 (FIG. 3), such that the voltage across the substrate 916 (and/or the substrate support 906) and the targets (e.g., target 920 and/or target 924) remains substantially constant (e.g., at least in terms of absolute value) during the deposition process. In some embodiments, the voltage is kept above about 200 V, such as between 200 V and 600 V (e.g., between about 300 V and 500V). As described above, operating the PVD tool 900 in such a manner during the deposition of the IGZO (i.e., as opposed to constant-power mode, which is typically used) enhances the crystalline structure of the IGZO, particularly along the (009) plane.

Although the PVD tool 900 shown in FIG. 9 includes a stationary substrate support 906, it should be understood that in a manufacturing environment, the substrate 916 may be in motion (e.g., an in-line configuration) during the formation of various layers described herein.

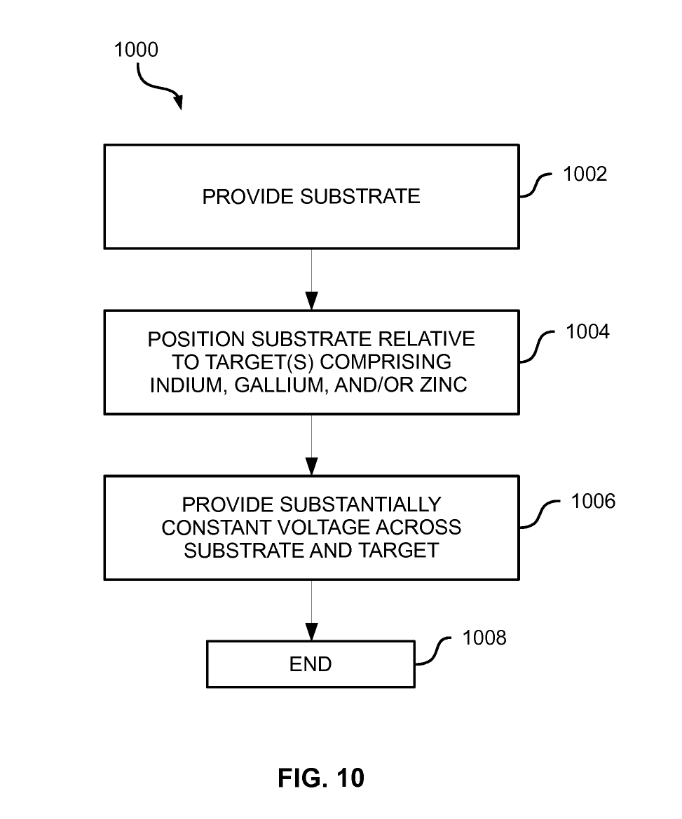

FIG. 10 illustrates a method 1000 for forming crystalline IGZO (or enhancing the crystalline structure of IGZO) according to some embodiments. At block 1002, the method 1000 begins with a substrate being provided (e.g., on a substrate support in a PVD tool processing chamber). As described above, the substrate may be made of glass.

At block 1004, the substrate is positioned relative to (e.g., below) a target, or multiple targets (e.g., within a PVD tool processing chamber). The target(s) include indium, gallium, zinc, or a combination thereof.

At block 1006, a substantially constant voltage across the substrate and the target(s) is provided. The substantially constant voltage causes a plasma species (e.g., to which the target is exposed within the PVD processing chamber) to impact the target, thus ejecting material from the target. The ejected material forms an IGZO layer above the substrate. In some embodiments, the substantially constant voltage is between about 200 V and about 600V. As described above, the substantially constant (and perhaps relatively high) voltage enhances the crystalline structure of the deposited IGZO.

In some embodiments, the IGZO layer is formed as a component (e.g., an IGZO channel layer) in an IGZO device, such as an IGZO TFT. As such, although not shown, in some embodiments, the method 1000 includes the formation of additional components for an IGZO device, such as the gate electrode, gate dielectric layer, source/drain regions, etc. At block 1008, the method 1000 ends.

Thus, in some embodiments, a method is provided. A substrate is positioned relative to at least one target. The at least one target includes indium, gallium, zinc, or a combination thereof. A substantially constant voltage is provided across the substrate and the at least one target to cause a plasma species to impact the at least one target. The impacting of the plasma species on the at least one target causes material to be ejected from the at least one target to form an IGZO layer above the substrate.

In some embodiments, a method for forming an IGZO device is provided. A substrate is positioned relative to least one target. The at least one target includes indium, gallium, zinc, or a combination thereof. A substantially constant voltage of between about 200 V and about 600 V is provided across the substrate and the at least one target to cause a plasma species to impact the at least one target. The impacting of the plasma species on the at least one target causes material to be ejected from the at least one target to form an IGZO layer above the substrate.

In some embodiments, a method for forming an IGZO device is provided. A substrate is positioned on a substrate support in a processing chamber of a PVD tool. The PVD tool also includes at least one target within the processing chamber. The at least one target includes indium, gallium, zinc, or a combination thereof. The PVD tool is operable in a constant-power mode, a constant-current mode, and a constant-voltage mode. The at least one target is exposed to a plasma species. A substantially constant voltage is provided across the substrate and the at least one target to cause a plasma species to impact the at least one target. The providing of the substantially constant voltage occurs with the PVD tool operating in the constant-voltage mode. The impacting of the plasma species on the at least one target causes material to be ejected from the at least one target to form an IGZO layer above the substrate.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method comprising:
positioning a substrate relative to at least one target, the at least one target comprising indium, gallium, zinc, or a combination thereof; and
providing a substantially constant voltage across the substrate and the at least one target to cause a plasma species to impact the at least one target,
wherein the impacting of the plasma species on the at least one target causes material to be ejected from the at least one target to form an indium-gallium-zinc oxide (IGZO) layer above the substrate.

2. The method of claim 1, wherein the substantially constant voltage is between about 200 V and about 600 V.

3. The method of claim 2, wherein the at least one target comprises a single target comprising indium, gallium, and zinc.

4. The method of claim 2, wherein the at least one target comprises a first target comprising indium and zinc and a second target comprising gallium.

5. The method of claim 1, further comprising forming a gate electrode above the substrate, wherein the IGZO layer is formed above the gate electrode.

6. The method of claim 5, further comprising forming a gate dielectric layer above the gate electrode, wherein the IGZO layer is formed above the gate dielectric layer.

7. The method of claim 6, further comprising forming a source region and a drain region above the IGZO layer.

8. A method for forming an indium-gallium-zinc oxide (IGZO) device, the method comprising:
positioning a substrate relative to at least one target, the at least one target comprising indium, gallium, zinc, or a combination thereof; and
providing a substantially constant voltage of between about 200 V and about 600 V across the substrate and the at least one target to cause a plasma species to impact the at least one target,
wherein the impacting of the plasma species on the at least one target causes material to be ejected from the at least one target to form an IGZO layer above the substrate.

9. The method of claim 8, wherein the providing of the substrate comprises positioning the substrate on a substrate support in a processing chamber of a physical vapor deposition (PVD) tool.

10. The method of claim 9, wherein the PVD tool is operable in a constant-power mode, a constant-current mode, and a constant-voltage mode, and the providing of the substantially constant voltage across the substrate and the at least one targets occurs with the PVD operating in the constant-voltage mode.

11. The method of claim 10, further comprising forming a gate electrode above the substrate, wherein the IGZO layer is formed above the gate electrode.

12. The method of claim 11, further comprising forming a gate dielectric layer above the gate electrode, wherein the IGZO layer is formed above the gate dielectric layer.

13. The method of claim 12, further comprising forming a source region and a drain region above the IGZO layer.

14. The method of claim 8, wherein the IGZO layer has a crystalline structure that is dominant along the c-axis.

15. A method for forming an indium-gallium-zinc oxide (IGZO) device, the method comprising:
positioning a substrate on a substrate support in a processing chamber of a physical vapor deposition (PVD) tool, wherein the PVD tool further comprises at least one target within the processing chamber, the at least one target comprising indium, gallium, zinc, or a combination thereof, and is operable in a constant-power mode, a constant-current mode, and a constant-voltage mode;
exposing the at least one target to a plasma species; and
providing a substantially constant voltage across the substrate and the at least one target to cause a plasma species to impact the at least one target, wherein the providing of the substantially constant voltage occurs with the PVD tool operating in the constant-voltage mode, and
wherein the impacting of the plasma species on the at least one target causes material to be ejected from the at least one target to form an IGZO layer above the substrate.

16. The method of claim 15, wherein the substantially constant voltage is between about 200 volts (V) and about 600 V.

17. The method of claim 16, further comprising forming a gate electrode above the substrate, wherein the IGZO layer is formed above the gate electrode.

18. The method of claim 17, further comprising forming a gate dielectric layer above the gate electrode, wherein the IGZO layer is formed above the gate dielectric layer.

19. The method of claim 18, further comprising forming a source region and a drain region above the IGZO layer.

20. The method of claim 19, further comprising forming a passivation layer above the source region and the drain region.
